(19) United States
(12) Patent Application Publication
(10) Pub. No.: US 2011/0304318 A1
(43) Pub. Date: Dec. 15, 2011

(54) FREQUENCY-SCALABLE SHOCKLINE-BASED SIGNAL-SOURCE EXTENSIONS

(75) Inventors: Karam Michael Noujeim, Los Altos, CA (US); Jon S. Martens, San Jose, CA (US)

(73) Assignee: ANRITSU COMPANY, Morgan Hill, CA (US)

(21) Appl. No.: 13/101,910

(22) Filed: May 5, 2011

Related U.S. Application Data
(63) Continuation-in-part of application No. 12/813,337, filed on Jun. 10, 2010.

(51) Int. Cl. G01R 23/16

(52) U.S. Cl. 324/76.24

(57) ABSTRACT

A system is provided using one or more shocklines or non-linear transmission lines (NLTLs) to extend the bandwidth of an RF signal source. Extension of the RF bandwidth is achieved by means of multiplexing as well as frequency scaling. Frequency scaling tailors the performance of each NLTL for operation in a particular output frequency band(s) by adjusting the varactor spacing in the NLTL. Multiplexing amalgamates the output frequency bands of one or more NLTLs, thus resulting in a broad output frequency range.

### CLAIM FOR PRIORITY

This application is a continuation-in-part of application Ser. No. 12/813,337 filed on Jun. 10, 2010, entitled “Frequency-Scalable Shockline-Based VNA,” which is incorporated by reference herein in its entirety.

### BACKGROUND

1. Technical Field

The present invention relates to components that extend the frequency range of a Vector Network Analyzer (VNA). More particularly, the present invention relates to high-frequency components such as non-linear transmission lines or shocklines that can be used to extend the RF source frequency of sampler-based VNAs to operate at high frequencies.

2. Related Art

### A. High-Frequency Sampler-Based VNA Receivers in General

Sampler-based VNA receivers make use of equivalent-time sampling to down-convert RF stimulus and response signals to lower intermediate-frequency (IF) signals. In effect, the samplers “time-stretch” coupled versions of RF signal waves incident on and reflected from a device under test (DUT). This sampling approach results in a simplified VNA architecture with reduced cost in comparison with one employing fundamental mixing where the RF-to-IF conversion is made using the fundamental local oscillator (LO) signal as opposed to a harmonic of the LO.

FIG. 1 shows a block diagram illustrating typical components of a sampler-based VNA. The RF signal generator 100 provides an RF signal through switch 102 to two possible paths 104 and 105 along which incident signals a1 and a2 are provided to a DUT 106. The RF signal is also coupled through couplers 108a and 110a as an RF reference signal to respective reference samplers 112a and 114a for down-conversion to IF reference signals IFₐ₁ and IFₐ₂. Signals b1 and b2 that are reflected from or transmitted through the DUT 106 are coupled through couplers 108b and 110b to respective test samplers 112b and 114b in the form of test signals for down-conversion to IF signals IF_{b1} and IF_{b2}. Analog-to-digital converters (not shown) convert the IFₐ₁, IFₐ₂, IF_{b1} and IF_{b2} to digital signals for processing and analysis that are geared at extracting the DUT response.

In each of the samplers 112a, 112b, 114a and 114b, the RF signal is mixed with a harmonic of the LO signal generator 120 to form the IF signals IFₐ₁, IF_{b1}, IFₐ₂ and IF_{b2}. The harmonic generator 122 connects LO signal generator 120 to the samplers 112a, 112b, 114a and 114b and provides harmonics of the fundamental LO signal generator 120, thereby increasing significantly the LO frequency provided to the samplers 112a, 112b, 114a and 114b.

As a direct result of the nature of the equivalent-time-sampling process, the LO source 120 required for strobing the samplers 112a, 112b, 114a and 114b operates in a lower frequency range than would be required in a fundamental-mixer VNA where the LO is directly connected to the mixers. Equivalent-time sampling, however, is provided at the expense of increased conversion loss.

### B. Sampler Circuitry

FIG. 2 shows one implementation of a sampling circuit that has been used extensively in microwave VNAs, sampling oscilloscopes, frequency counters, etc. The sampling circuit of FIG. 2 can be used to form samplers 112a, 112b, 114a and 114b of FIG. 1. The circuit of FIG. 2 was introduced by W. M Grove in “Sampling for Oscilloscopes and Other RF Systems: DC Through X-Band,” IEEE MTT, Vol. 66, No. 1, May 1966. In this sampler circuit, a voltage pulse V_{LO} is generated by signal source 200 (which can be formed by the output of harmonic generator 122 of FIG. 1). The V_{LO} source 200 is provided through source resistance 201 (R_{S-LO}). The signal V_{LO} gates the Schottky diodes 202 and 203 over a brief time interval T_{g}, known also as the gating time. Over this interval, the Schottky diodes 202 and 203 are driven into conduction and result in charging of the sampling capacitors 204 and 206 having a capacitance labeled C_{S}. The charge present on the capacitors 204 and 206 results in an output waveform provided at V_{IF} through resistors 220 and 222 with value R_{F} that is related to the polarity and amplitude of the RF input from V_{RF} source 208. The signal from RF source 208 is provided through a resistor divider with resistors 210 and 211 each having a resistance R_{S}. The voltage pulse provided across the sampling bridge (i.e. series connection of 204, 203, 202, 206) is formed by differentiating the step-like voltage waveform generated from the V_{LO} source 200 by means of a pair of commensurate-length shorted stubs (210,212) and (214,218) located on either side of the sampling bridge. To elaborate, transmission lines (212, 210) and (214, 218) are shorted and used to transform a step voltage from V_{LO} source 200 into a pulse that gates the sampling Schottky diodes 202 and 203. The voltage at V_{IF} is further shaped by a filter formed by capacitor 224 (C_{H}) and resistor 226 (R_{L}) connecting the output V_{IF} to ground.

FIG. 3 shows an equivalent circuit for the components of FIG. 2. The equivalent circuit for a Schottky diode is a series combination of a Schottky diode junction resistance Rj 302, its ohmic resistance Rd 304, and an ideal switch gated at the rate of the V_{LO} source. The equivalent circuit of FIG. 3 thus includes the switched gate 300 driven by the V_{LO} source, along with the junction resistance Rj/2 302 and ohmic resistance Rd/2 304 that are equivalent to the combined diodes 202 and 203. The RF source 208 has an equivalent voltage V_{RF}/2 at 308 connected to an equivalent resistance Rs/2 310 for resistors 210 and 211. The capacitors 204 and 206 have an equivalent capacitance 2Cs 306, while filter resistors 220 and 221 have an equivalent resistance R_{F}/2 320. The output filter keeps the same values Cs 324 and R_{L} 326 as elements 224 and 226 of FIG. 2.

The 3-dB RF bandwidth of the sampler shown having the equivalent circuit shown in FIG. 3 will be inversely proportional to the gating time T_{g} (that is, f_{3-dBRF}≈0.35/T_{g}). For a given RF frequency f_{RF}, the LO frequency is then chosen to reduce the harmonic number N and, thus, the conversion loss and noise figure of the sampler.

### C. Samplers Using Step Recovery Diodes

Practical implementations of samplers for VNAs have relied traditionally on step-recovery diodes (SRD) connected as V_{LO} source 200 to generate pulses applied to the switches. Commercial SRDs are traditionally limited to LO inputs having frequencies that do not exceed a few hundred MHz. This is due to the fact that the transit time of an SRD limits the frequency of its input. This limitation is a fundamental one in the context of microwave and millimeter-wave VNAs since it requires that a high harmonic number N be used in the down-conversion process, resulting in an increase in the noise figure of the sampler due to image-response conversion. In addition, the use of a high harmonic number increases the number of spurious receiver responses and can reduce the effective dynamic range of a VNA.

Another fundamental limitation in an SRD-based VNA is the RF leakage between channels. Because SRDs are fundamentally governed by avalanche phenomena, a single SRD is typically used for all channels of the VNA's receiver. If a separate SRD were used in each channel, the gating pulses would not be synchronous and the phase relationship between the receiver channels would not be stable. As a result, the distribution scheme shown in FIG. 4 is commonly used with a single SRD in order to keep receiver channels synchronous.

FIG. 4 illustrates a VNA configuration with a single SRD circuit 405 to drive the four separate samplers 412a, 412b, 414a and 414b in a two-channel VNA. The SRD 405 is driven by a V_{LO} source 420 with its resistance R_{S-LO} 421, similar to source 200 and resistance 201 of FIG. 2. The signal from the SRD circuit 405 generates pulses that are distributed from power splitter 407 to the four samplers 412a, 412b, 414a and 414b. Each of the samplers can include circuitry similar to that shown in FIG. 2 that is supplied by the V_{LO} source 200 and resistor 201. The reference sampler 412a and test sampler 412b downconvert signals for a first channel A, similar to samplers 212a and 212b of the VNA circuitry of FIG. 2. The reference sampler 414a and test sampler 414b downconvert signals for a second channel B, similar to samplers 214a and 214b of FIG. 2. In channel A, an RF signal is provided from V_{RF-A} source 400a through couplers 408a and 408b to a first port of a highly reflective DUT 406. In channel B, an RF signal from V_{RF-B} source 400a at the second port of DUT 406 is provided through couplers 410a and 410b to a load 400b. The couplers 408a and 408b of channel A provide a similar function to couplers 108a and 108b of FIG. 1. Similarly, couplers 410a and 410b of channel B provide a similar function to couplers 110a and 110b of FIG. 1.

The leakage between channels A and B even with a single SRD 405 can occur in the path between the channels illustrated by dashed lines in FIG. 4. Leakage can occur between samplers 412a, 412b, 414a and 414b, since the SRD output frequency must be high and isolation amplifiers cannot be used. Thus with a purely passive network, there is an isolation limitation (signals leak from one sampler, through the distribution network, into another sampler). Thus, it is desirable to provide other alternatives to create LO signals to drive samplers other than the SRD approach for a high-frequency VNA/measuring transceiver.

### D. Samplers Based on Nonlinear Transmission Lines

A nonlinear transmission line (NLTL) provides a distributed alternative to the SRD, thereby providing a V_{LO} signal source 200 for VNA samplers that can operate over a broad range to very high frequencies and experience minimal channel leakage. SRDs made possible the extension of the RF bandwidth in VNAs to 65 GHz. An example of an SRD-based sampling VNA operating to 65 GHz is the Lightning VNA 37397D manufactured by Anritsu Company of Morgan Hill, Calif. But achieving frequencies above 65 GHz using SRDs has been prevented by the limited fall time for the SRD-based samplers. This frequency limitation, however, can be far removed using NLTLs or shocklines.

FIG. 5 shows representative circuit of a sampler-based VNA using NLTLs 561-564 to provide the LO input to samplers 512a, 512b, 514a and 514b. NLTLs are distributed devices that support the propagation of nonlinear electrical waves such as shocks and solitons. As shown by NLTL 561 of FIG. 5, the NLTL is made up of high-impedance transmission line (571,572) loaded periodically with varactor diodes 573 forming a propagation medium whose phase velocity, and thus time delay, is a function of the instantaneous voltage. For a step-like waveform, the trough of the wave travels at a faster phase velocity than the peak, resulting in compression of the fall time, and thus the formation of a steep wave front that approaches that of a shock wave.

Shockline-based samplers, whether used in a VNA or other receivers to achieve very high frequency operation, have been the subject of patents and numerous articles. For example, shockline devices for use in samplers are described in the following: U.S. Pat. No. 5,014,018 entitled “Nonlinear Transmission Line for Generation of Picosecond Electrical Transients,” by Rodwell, et al.; U.S. Pat. No. 7,088,111 entitled “Enhanced Isolation Level Between Sampling Channels in A Vector Network Analyzer,” by K. Noujeim; and U.S. Pat. No. 6,894,581 entitled “Monolithic Nonlinear Transmission Lines and Sampling Circuits with Reduced Shock-Wave-to-Surface-Wave Coupling,” by K. Noujeim.

In contrast with an SRD where output frequencies are limited to tens of GHz, an NLTL can be designed to generate output frequencies spanning hundreds of GHz, making it ideal for gating samplers whose bandwidth exceeds by far that of the aforementioned 65 GHz SRD-based sampler. In fact, it is the NLTL's frequency-scalable input and output that set it apart from SRDs' and allow broadband sampler operation based on lower harmonic numbers, thus resulting in improved noise figure and spurious responses. The input and output frequency ranges of an NLTL are predicted by its input and output Bragg cutoff frequencies, which are a function of the spacing d (shown in NLTL 551) between cells in a shockline as indicated in U.S. Pat. No. 5,014,018 referenced previously. When driven with a sinusoidal signal, such as the V_{LO} signal 520 in FIG. 5, the NLTL circuit compresses the signal's fall time, resulting in a waveform that is rich in high-frequency harmonics. Monolithic implementations of this circuit and derivatives thereof have recently been made on GaAs substrates. See for example, U.S. Pat. No. 4,956,568 entitled “Monolithic Sampler,” by Sy et al; and U.S. Pat. Nos. 5,267,020 and 5,378,939 entitled “Gallium Arsenide Monolithically Integrated Sampling Head Using Equivalent Time Sampling Having a Bandwidth Greater Than 100 GHz,” by Marsland et al. These shockline implementations dealt with the generation of picosecond pulses for the purpose of gating samplers, making possible the down-conversion of extremely high frequency millimeter-wave and submillimeter-wave signals based on the use of lower harmonic numbers, and resulting in the concomitant improvement in noise figure and spurious responses.

FIG. 5 further illustrates that with NLTLs, as opposed to SRDs, a separate one of the NLTLs 561-564 can be used to supply each sampler 512a, 512b, 514a and 514b. Use of separate NLTLs with each sampler does not impact the gating-pulse synchronicity between samplers. This results from the stability of the distributed fall-time compression mechanism in a shockline (or NLTL), and is in sharp contrast with an SRD in which fall time is based on device-dependent charge storage.

FIG. 5 further illustrates that with NLTLs, as opposed to SRDs, isolators 531-534, amplifiers 541-544 and filters 551-554 can be used to improve channel-to-channel isolation. This is possible since amplifiers covering the input frequency range of a shockline provided by the source V_{LO} 520 are feasible. This is in direct contrast with an SRD whose output frequencies are over a range that exceeds that of available amplifiers and isolators. The availability of isolators 531-534, amplifiers 541-544 and filters 551-554 for use with NLTLs is described in U.S. Pat. No. 7,088,111, referenced previously.

Similar to FIG. 4, the circuitry of channel A in FIG. 5 includes an RF signal provided from V_{RF-A} source 500a through couplers 508a and 508b to a first port of DUT 506. In channel B, an RF signal from the V_{RF-A} source 500a at the second port of DUT 506 is provided through couplers 510a and 510b to a load 500b. The couplers 508a and 508b of channel A provide a similar function to couplers 108a and 108b of FIGS. 1, and 408a and 408b of FIG. 4. Similarly, couplers 410a and 410b of channel B provide a similar function to couplers 110a and 110b of FIGS. 1, and 408a and 408b of FIG. 4. The leakage between channels A and B, though smaller than leakage experienced with the SRD circuitry of FIG. 4, can occur in the path between channels A and B that is illustrated by dashed lines in FIG. 5.

It would be desirable to provide circuitry to make NLTLs or shocklines even more amenable for use in VNAs.

### SUMMARY

Embodiments of the present invention provide a system using one or more NLTLs to extend the bandwidth of an RF signal source. The NLTL RF source extension assembly can be used in systems such as a VNA system that uses NLTL-based samplers that receive and downconvert broadband high frequency signals, as well as tracking generators, synthesizers and other instruments.

Scaling to adjust electrical performance vs. frequency is accomplished by the use of multiplexing as well as frequency scaling. Frequency scaling is accomplished to fine tune the frequency vs. performance of an individual NLTL. Multiplexing allows the output of a single or multiple NLTLs to be fine tuned. Multiplexing can be accomplished using couplers or switches.

Frequency scalability of an NLTL is accomplished by increasing or decreasing the Bragg frequency of an NLTL, thus tuning its millimeter-wave harmonic content over a desired frequency range. The Bragg cutoff frequency of the NLTL can be increased or decreased by changing the spacing between varactor diodes of the NLTL, so as to either reduce or increase the fall time of its output voltage waveform. Setting the spacing between varactor diodes, thus, allows scaling by shrinking or expanding the sampling pulse width.

Multiplexing allows different segments of the desired overall frequency range to be amalgamated, and is amenable to frequency scaling. One of several multiplexed configurations can be used. In one configuration, a single NLTL is provided with its output multiplexed through different sets of filters to enable enhancing the desired frequency response in each filter segment. In another configuration, the output of an RF signal source is multiplexed through multiple NLTLs. The spacing between the varactor diodes in each NLTL segment is then set differently to enhance the frequency performance for each segment.

### BRIEF DESCRIPTION OF THE DRAWINGS

Further details of the present invention are explained with the help of the attached drawings in which:

FIG. 1 is a block diagram illustrating typical components of a sampler-based VNA;

FIG. 2 shows one implementation of a sampling circuit that can be used in FIG. 1;

FIG. 3 shows an equivalent circuit for the components of FIG. 2;

FIG. 4 illustrates a sampler-based VNA configuration that uses a single step recovery diode (SRD) circuit to drive the four separate samplers in a two channel VNA;

FIG. 5 shows a sampler-based VNA using shocklines (NLTLs) to provide the LO input to samplers;

FIG. 6 shows a time-domain illustration of an equivalent-timesampling process wherein an ideal switch gated at a rate 1/T_{LO} by a V_{LO} signal samples an RF signal V_{RF} with a gating time of Tg to produce an output V_{IF};

FIG. 7 shows the magnitude response vs. frequency of the ideal switch of FIG. 6 where a change in gating time Tg affects RF bandwidth;

FIG. 8 shows one NLTL sampling circuit segment that can be multiplexed with other segments to form a shockline-based sampling reflectometer that operates over a wide bandwidth with a desired frequency vs. noise response;

FIG. 9 shows one embodiment of circuitry for multiplexing reflectometer segments as shown in FIG. 8 to form a broadband reflectometer using a coupler-based LO distribution network;

FIG. 10 shows an alternative reflectometer configuration to FIG. 9 that includes an LO distribution network with different LO coupler connections;

FIG. 11 shows another alternative reflectometer configuration to FIG. 9 that includes an LO distribution network without using couplers;

FIG. 12 shows an NLTL sampling circuit segment alternative to FIG. 8 that can be multiplexed with other segments to form a shockline-based sampling reflectometer;

FIG. 13 shows one embodiment of circuitry for multiplexing reflectometer segments as shown in FIG. 12 to form a reflectometer using a coupler-based LO distribution network;

FIG. 14 shows an alternative reflectometer configuration to FIG. 13 that includes an LO distribution network with different LO coupler connections;

FIG. 15 shows another alternative reflectometer configuration to FIG. 13 that includes an LO distribution network without using couplers;

FIG. 16 shows a first configuration of circuitry to implement a shockline based RF source extension that uses a single shockline;

FIG. 17 shows a second configuration of circuitry to implement a shockline based RF source extension that uses multiple shocklines; and

FIG. 18 shows a third configuration of circuitry to implement a shockline based RF source extension that eliminates the need for couplers.

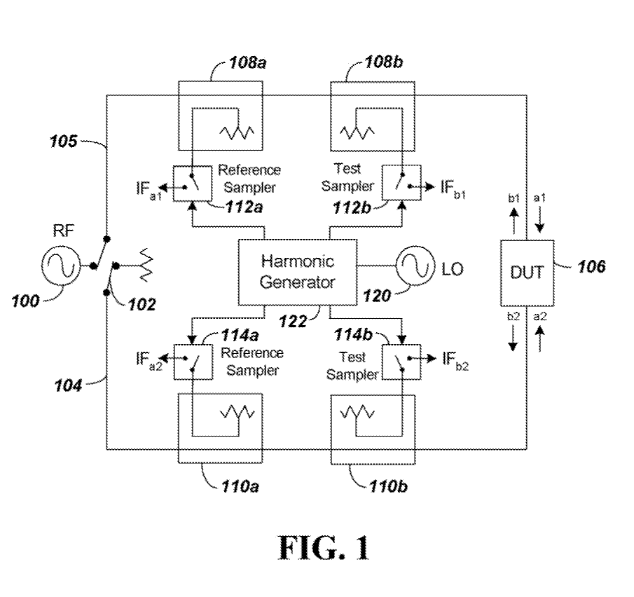

### DETAILED DESCRIPTION

Components of embodiments of the present invention provide a system using NLTLs to extend the frequency range of an RF source. The RF source extension system can be used in conjunction with a VNA system that uses NLTL-based samplers that receive and downconvert broadband high frequency signals. To facilitate understanding of the use of the RF source extension system in embodiments of the present invention, a NLTL-based sampler system is first described to follow.

### I. Sampler Based NLTL System

To accomplish frequency scaling when using NLTLs in embodiments of the present invention, it is initially realized that by changing gating time, Tg, frequency vs. RF conversion efficiency can be controlled. A reduction in the gating time Tg of the sampling Schottky diodes can be shown to provide an increase in RF bandwidth at the expense of reduced conversion efficiency. Adjusting the Bragg frequency of the NLTL as well as the length of the shorted stubs in the sampler changes this gating time, Tg, and thus allows scaling of the sampler's RF bandwidth.

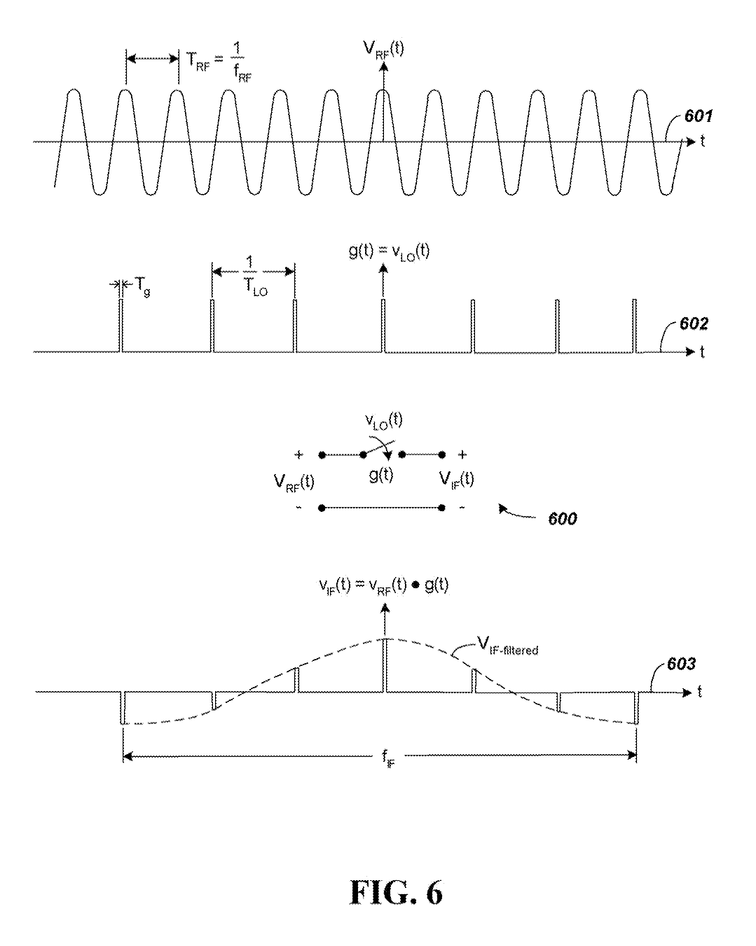

FIG. 6 shows a time-domain illustration of a harmonic sampling process wherein an ideal switch gated by a V_{LO} signal at a rate 1/T_{LO} samples an RF signal V_{RF} with a gating time of Tg to produce an output V_{IF}. The plots of FIG. 6 illustrate the effect of adjusting gating time Tg in the switch with the realization that the periodic nature of the RF waves makes possible their down-conversion by equivalent-time sampling, also known as under-sampling, harmonic sampling, or super-Nyquist sampling.

In FIG. 6, plot 601 shows the RF voltage waveform V_{RF} applied to ideal switch circuit 600 over time t. The sinusoidal voltage V_{RF}(t)=Acos(2πf_{RF}(t)) shown has a period T_{RF}. Plot 602 shows the effect of periodically connecting the switch 600 having a conductance g(t) at a switching rate T_{LO}=1/f_{LO} with a gating aperture Tg. The conductance g(t) is plotted versus time, with conductance controlled by the LO voltage V_{LO} so that g(t)=V_{LO}(t). The final plot 603 shows the v_{IF}(t) output of switch 600 providing a down-converted IF waveform. A dashed line in plot 603 also shows a low-pass filtered version of the v_{IF}(t) output pulses V_{IF-filtered}. Evident from plot 603 is the fact that the sampled IF waveform v_{IF}(t) is the arithmetic product of the sinusoidal RF waveform v_{RF}(t) of plot 601 and the ideal switch conductance g(t) of plot 602.

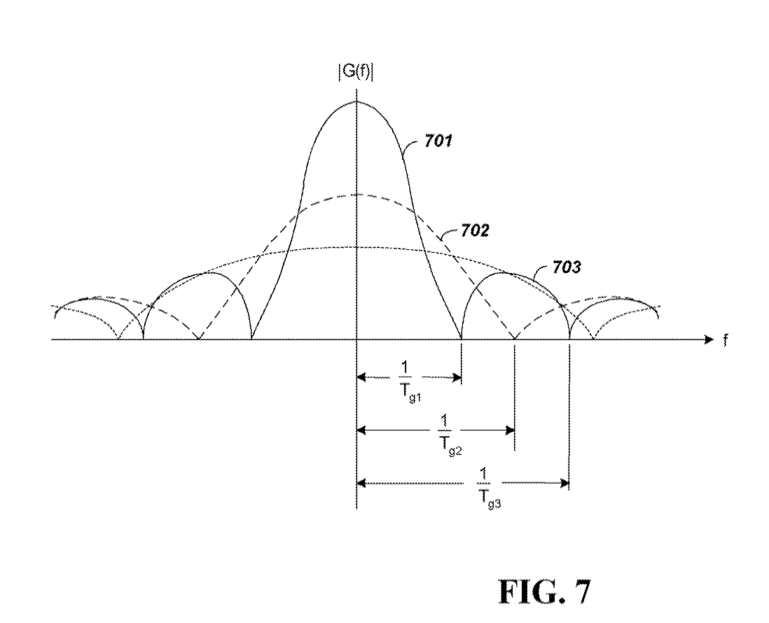

FIG. 7 shows the magnitude response vs. frequency plot of ideal switch 600 of FIG. 6 which illustrates how a change in gating time Tg affects RF bandwidth. A reduction in the gating time Tg from one pulse to another is shown accompanied by an increase in RF bandwidth at the expense of reduced conversion efficiency. A first pulse 701 has the longest gating time T_{g1}, and hence the shortest RF frequency response f_{g1}=1/T_{g1}. The accompanying magnitude response of the pulse 701 and pulse width is highest, indicating conversion efficiency is highest. However, the longer gating time pulse 701 corresponds to a lower Bragg cutoff frequency for the NLTL. A second dashed pulse 702 shows a slight decrease in gating time T_{g2}, with an accompanying increase in RF bandwidth and decrease in conversion efficiency relative to pulse 701. Finally a dotted pulse 703 shows another decrease in gating time T_{g3}, and its further increase in RF bandwidth and decrease in conversion efficiency relative to pulse 701. With the switching device 600 made using a shockline-based sampler, an increase in the LO drive frequency and the Bragg cutoff frequency of the NLTL (i.e. shockline) shortens its fall time, thus reducing the gating time Tg of the sampler, resulting in a wider sampler RF bandwidth at the expense of reduced conversion efficiency.

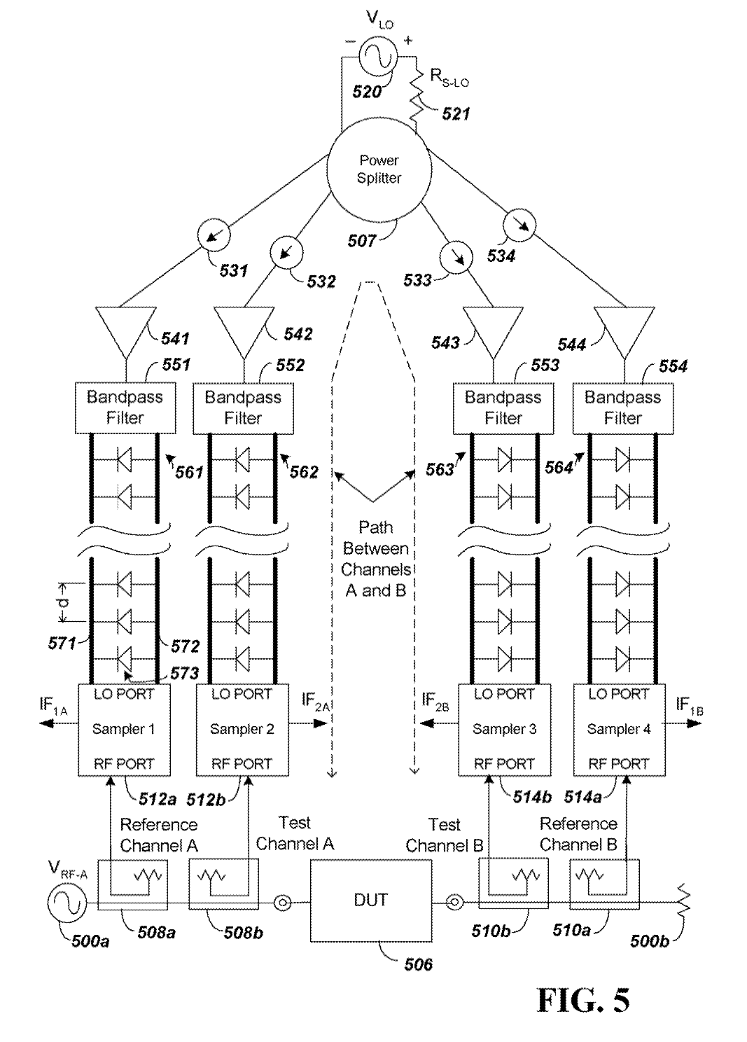

With FIGS. 5 and 6 in mind, embodiments of the present invention are provided that control a tradeoff between noise and bandwidth using scaling of the LO drive frequency and the gating time Tg of NLTL-based samplers. Thus unlike an SRD-driven sampler, an NLTL-based sampler can be adjusted for optimal noise and bandwidth performance.

Scaling is thus used according to embodiments of the present invention to adjust noise performance vs. frequency by applying the following methods: (1) increasing or decreasing the Bragg cutoff frequency of the shockline, such as by changing the spacing d between varactor diodes of the NLTL, so as to either reduce or increase the gating time, Tg, of the NLTL-driven sampler; (2) changing the structure of the pulse forming network connected with the sampler, such as by changing the length of the voltage-step differentiator arms in the pulse forming network; and (3) changing the LO signal applied to the shockline. These three methods used together can accomplish scaling while optimizing the tradeoff between conversion loss and RF bandwidth.

Methods 1, 2 and 3 go hand in hand and are used together in order to extend the RF bandwidth of a VNA and optimize its noise performance. Method 1 scales the NLTL in order to reduce its fall time and thus extend its output for operation at high frequencies. Method 2 takes the output of that scaled NLTL and turns it into a pulse that is used to gate the Schottky switch/sampler over the appropriate frequency range. Method 3 picks the LO frequency range that results in optimal RF bandwidth and noise performance when using the scaling of method 1 and sampler gating in method 2.

Specifics to accomplish methods 1, 2 and 3 are detailed to follow. First, in method 1, the NLTLs of FIG. 5 are replaced with multiple NLTLs each having different frequency characteristics that are multiplexed to allow selection of one of the NLTLs to achieve overall broadband performance. To adjust the frequency characteristics between NLTLs, the spacing d between varactors is reduced gradually as one travels from the input of an NLTL to its output. This results in efficient NLTL fall-time compression, or equivalently, more efficient pulse generation. By using this non-uniform spacing between varactors, it is best practice not to generally refer to a single Bragg cutoff frequency for the NLTL. The scenario, instead, changes to two Bragg cutoff frequencies: one for the input of the NLTL and the other for its output. However, for the sake of convenience, a single Bragg cutoff frequency is still referenced herein.

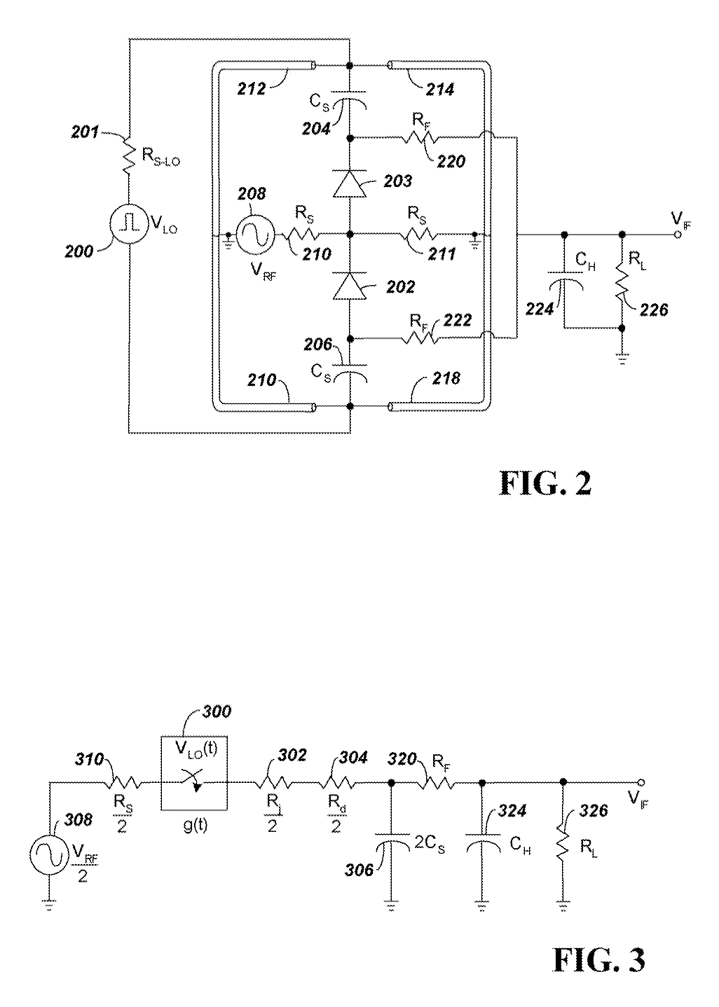

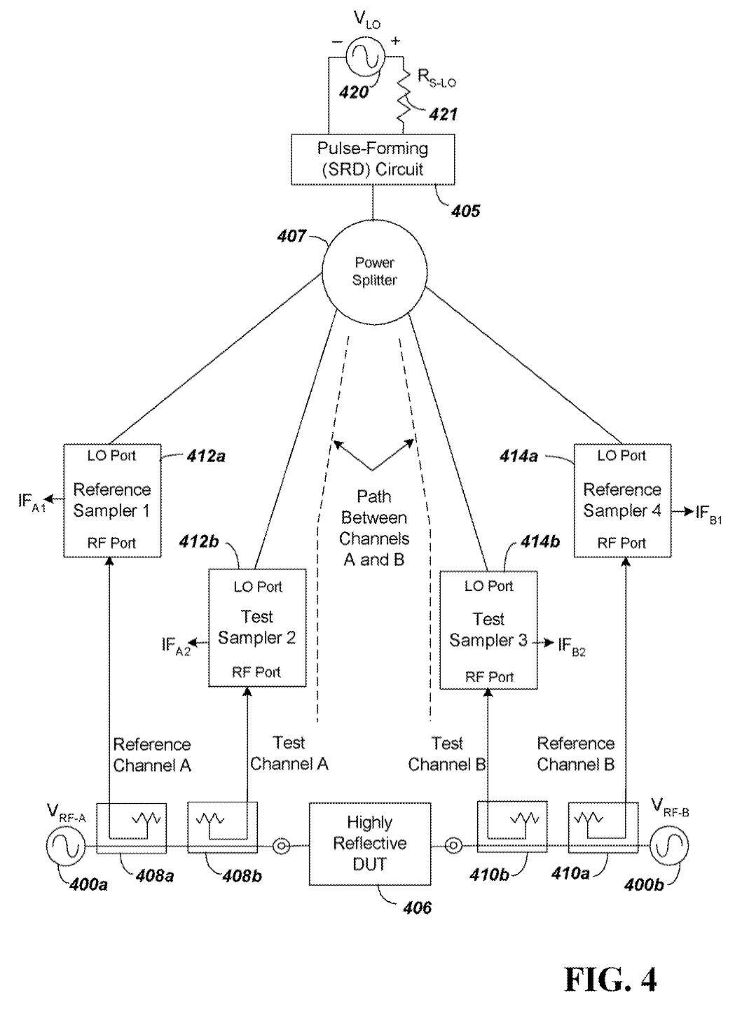

For methods 2 and 3, simple modifications can be made to the VNA reflectometer circuitry to enable scaling. For method 2, referring to FIG. 2, the length of the stubs (210, 212), and (214, 218) can be physically changed in the sampler. For method 3, the V_{LO} signal source 520 shown in FIG. 5 can have a frequency set, or alternatively a crystal or other fixed frequency reference can be provided with a desired operation frequency to optimize the overall performance in methods 1 and 2.

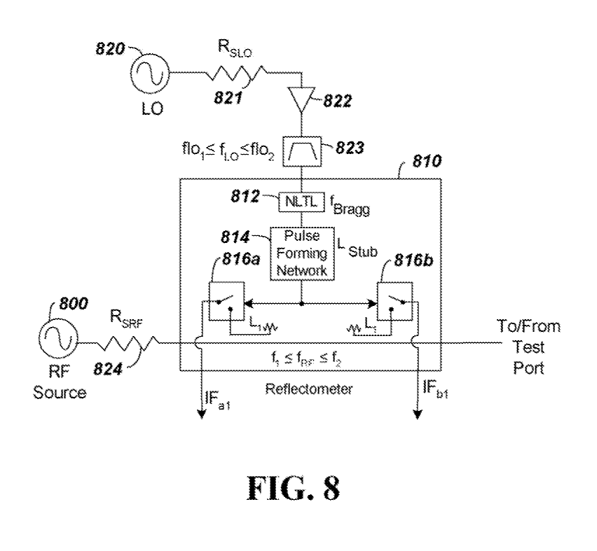

FIG. 8 shows one NLTL sampling circuit segment 810 that can be multiplexed with other segments to form a shockline-based sampling reflectometer. The multiplexed circuit segment of FIG. 8 allows use of methods (1)-(3) to optimize for different LO and RF frequency ranges in each segment. The circuit segment 810 of FIG. 8 is intended to replace shocklines and associated circuitry in one channel for example, such as shocklines 561-562, samplers 512a, 512b and couplers 808a, 808b of FIG. 5.

The components of the reflectometer segment 810 of FIG. 8 include a series connected shockline, or NLTL, 812 and pulse-forming network 814. The NLTL 812 receives an input from LO source 820 through bandpass filter 823. The pulse forming network 814, and samplers, 816a and 816b can have circuitry as shown in FIG. 2. The output of the pulse-forming network 814 is connected by a splitter to a first input of samplers 816a and 816b. The second input of sampler 816a is connected by a coupler to receive a signal from the RF source 800, while a coupler also provides a test signal from a test port to sampler 816b. The outputs of the samplers 816a and 816b then provide respective IF signals IFₐ₁ and IF_{b1}.

In FIG. 8, the reflectometer section 810 can have components selected to optimize performance for a given bandwidth. For example, the dimension d between the varactor diodes of the shockline in each reflectometer section can be different, the size of the differentiator arms can be different in the samplers, or a combination of these features could be changed between the reflectometers to accomplish a selective scaling. Varying components of the reflectometers 810 to change the Bragg frequency f_{Bragg} enables the operation bandwidth f_{RF} to change as shown in the drawings from f1<f_{RF}<f2. The length L_{Stub} of pulse forming network 814 can likewise be varied to accomplish scaling, as described above. The couplers of the reflectometer section 880 have a variable length, shown as L₁, to match the RF bandwidth of the samplers.

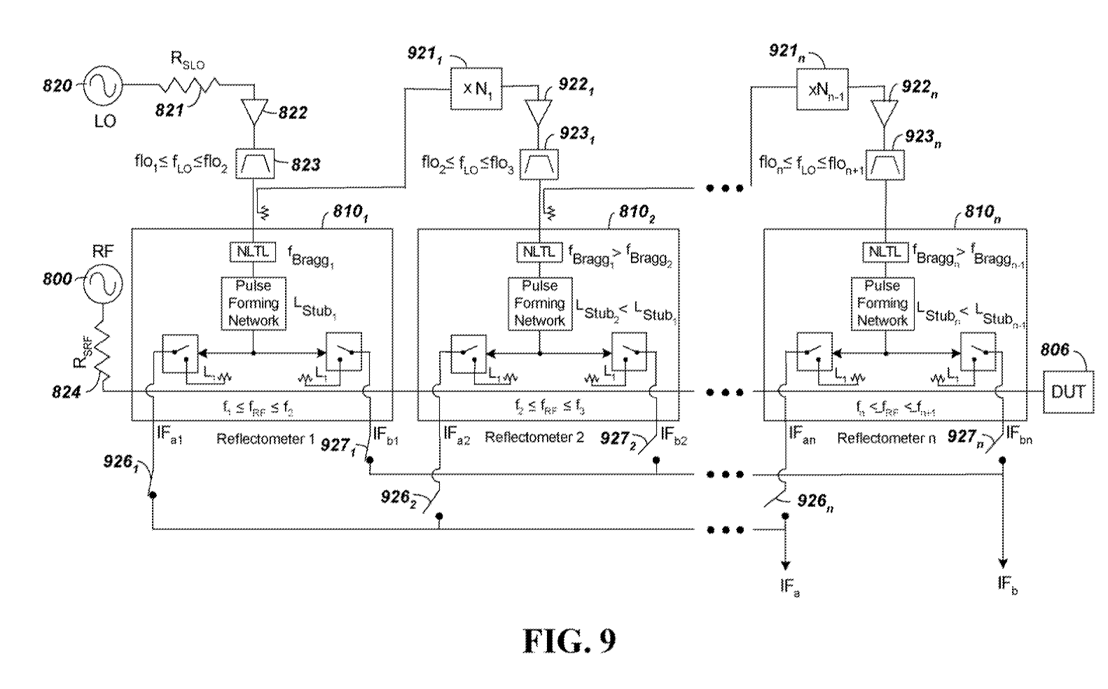

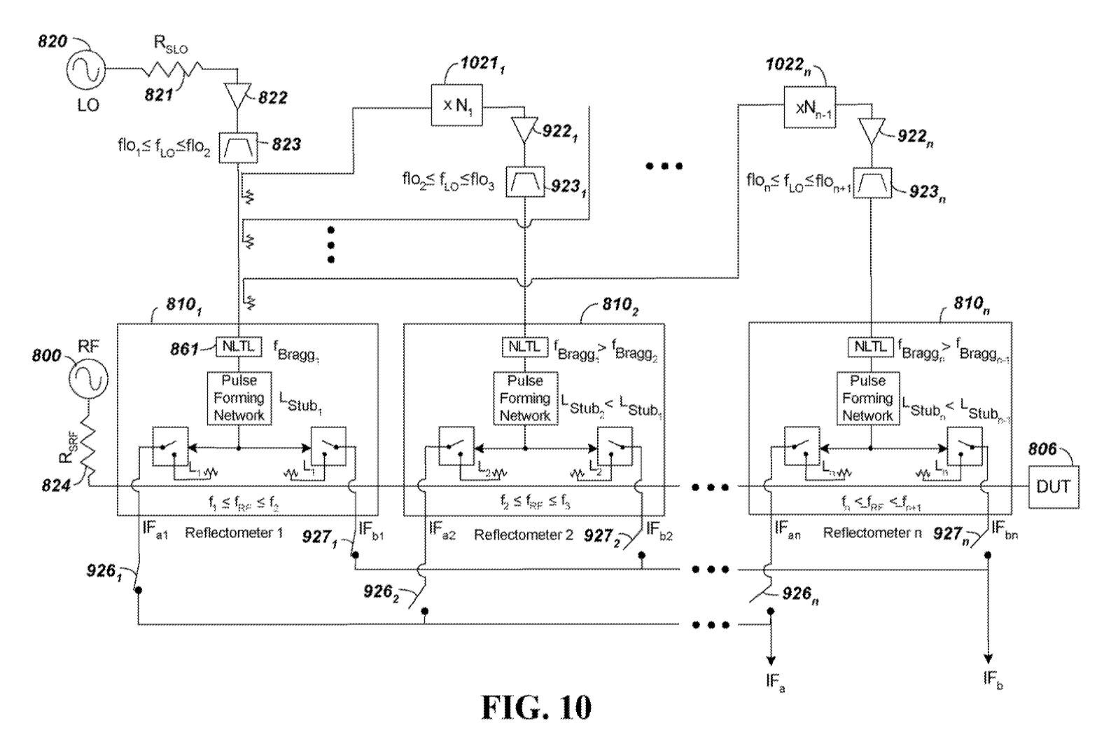

Common components that feed the reflectometer section 810 in FIG. 8 will also be used to feed other multiplexed reflectometer sections described in subsequent FIGS. 9 and 10. These common components include the LO source 820 that can be provided with a varying frequency range to reflectometers to accomplish a desired scaling. The LO source 820 is connected through a resistance R_{SLO} 821, amplifier 822 and bandpass filter 823 to the input of the NLTL in the reflectometer section 810. The bandpass filter 823 can be adjusted to the LO frequency provided to the individual reflectometer section, and is shown having the frequency range f_{LO} between f_{LO1} and f_{LO2}. As indicated above the LO frequency can be adjusted to optimize performance for a given bandwidth. The RF source 800 is another common element that is connected through a resistance 824 to the reflectometer section 880.

The primary factors that limit the bandwidth of the single reflectometer of FIG. 8 are as follows. First, the couplers connecting the RF to samplers 816a and 816b have operation restricted to the frequency range f₁<f_{RF}<f₂. Second the pulse forming network 814 has a restricted bandwidth of operation in the range of f_{LO1}<f_{LO}<f_{LO2} which can require high harmonic numbers be use for down conversion in samplers 816a and 816b resulting in reduced performance. Further the bandwidth of the LO has a limited range. Multiplexing as provided in FIGS. 9 and 10 help resolve these limiting factors.

FIG. 9 shows one embodiment of circuitry for multiplexing the reflectometer segments of FIG. 8 to form a broadband reflectometer with sections having a desired frequency vs. noise response. The reflectometer segments include segments 810₁₋ₙ that include components similar to those of reflectometer 810 in FIG. 8, so those components are not individually labeled. The internal components of the segments 800₁₋ₙ include components adjusted so they operate over different successive frequency ranges. For instance reflectometer segment 810₁ has components set so that the RF frequency range F_{RF} is f₁≦F_{RF}≦f₂. The next reflectometer segment 810₂ has an F_{RF} occupying the next frequency range f₂≦F_{RF}≦f₃, and so forth till the final segment 810ₙ that occupies the RF the frequency range fₙ₋₁≦F_{RF}≦fₙ.

To accomplish the different F_{RF} bands, the Bragg cutoff frequencies of the NLTLs are varied, as are the stub lengths of the pulse forming network and the length of the couplers. In reflectometer segment 810₁ the NLTL has a Bragg frequency f_{Bragg} set to sequentially lower values, with f_{Bragg1} of segment 810₁ being less than f_{Bragg2} of segment 810₂ and so forth till f_{Braggn} which is less than fBraggn₋₁ in segment 810ₙ. The Bragg cutoff frequency is varied by changing the distance d between varactor diodes of the NLTL as discussed with respect to FIG. 5, and can be controlled by setting the desired gating time Tg as discussed with respect to FIG. 7. The length of stubs in the pulse forming network also are changed to control bandwidth. The stubs of a first size L_{Stub1} are provided in segment 810₁, a slightly greater size L_{Stub2} is provided in segment 810₂ and larger sizes continue until the largest stub L_{Stubn} is provided in segment 810ₙ. Adjusting the stub size in the pulse-forming network to change the operation bandwidth is described previously with respect to FIG. 2. Further the lengths of the couplers are changed to sequentially greater frequency ranges and have a size beginning at L₁ in segment 810₁ that increases to Lₙ in segment 810ₙ to provide the overall desired bandwidth.

To provide an LO distribution system, an increasingly higher frequency LO signal range is provided to each sequential reflectometer segment 810₁₋ₙ. For the first segment 880₁, the LO source 820 in FIG. 9 is provided through a resistance R_{SLO} 821, amplifier 822 and bandpass filter 823 to the input of the NTLT in the reflectometer section 810₁ similar to the segment 810 of FIG. 8. For the next segment 880₂, the output of bandpass filter 823 is provided by a coupler to frequency multiplier 921₁ through amplifier 922₁ and bandpass filter 923₁ to the input of its NLTL. The frequency multiplier 921₁ has a multiplier value N₁ set to provide a slightly increased f_{LO} from f1≦f_{LO}≦f2 in segment 810₁ to f2≦f_{LO}≦f3 for segment 810₂. A similar coupler connects the LO in subsequent segments after 810₂. For instance, the output of bandpass filter 923₁ is provided to a subsequent frequency multiplier, and the coupling circuitry arrangement continues up to multiplier 921ₙ with value Nₙ₋₁. The output of multiplier 921ₙ then supplies amplifier 922ₙ and bandpass filter 923ₙ to create an f_{LO} of fₙ≦f_{LO}≦fₙ₋₁ that is input to segment 810ₙ.

The multiplexing circuitry of FIG. 9 also includes an IF distribution system with a series of switches 926₁₋ₙ and 927₁₋ₙ that individually connect the IF outputs of the segments 810₁₋ₙ to provide output IF signals IFa and IFb. The switch 926₁ selectively connects the reference IF signal from segment 810₁ to provide IFa, while switch 927₁ selectively connects the test signal from segment 810₁ to provide IFb. Similarly, switches 926₂ and 927₂ connect the IF outputs of segment 810₂, and switch circuitry continues up to 926ₙ and 927ₙ that selectively provide IF signals from the output of segment 810ₙ. A controller (not shown) connects the desired pair of switches in 926₁₋ₙ and 927₁₋ₙ to connect a desired one of reflectometer segments 810₁₋ₙ to provide the IFa and IFb outputs.

FIG. 10 shows an alternative reflectometer configuration to FIG. 9 that includes an LO distribution circuitry with different coupling connections. The LO distribution circuitry in FIG. 10 is changed from FIG. 9 to include frequency multipliers 1021₁₋ₙ that all connect by couplers between the output of bandpass filter 823 and the input of the first reflectometer segment 824. This configuration prevents the frequency multiplier values N₁ through Nₙ₋₁ from adversely affecting one another, as do the multipliers 921₁₋ₙ in FIG. 9 that are interconnected.

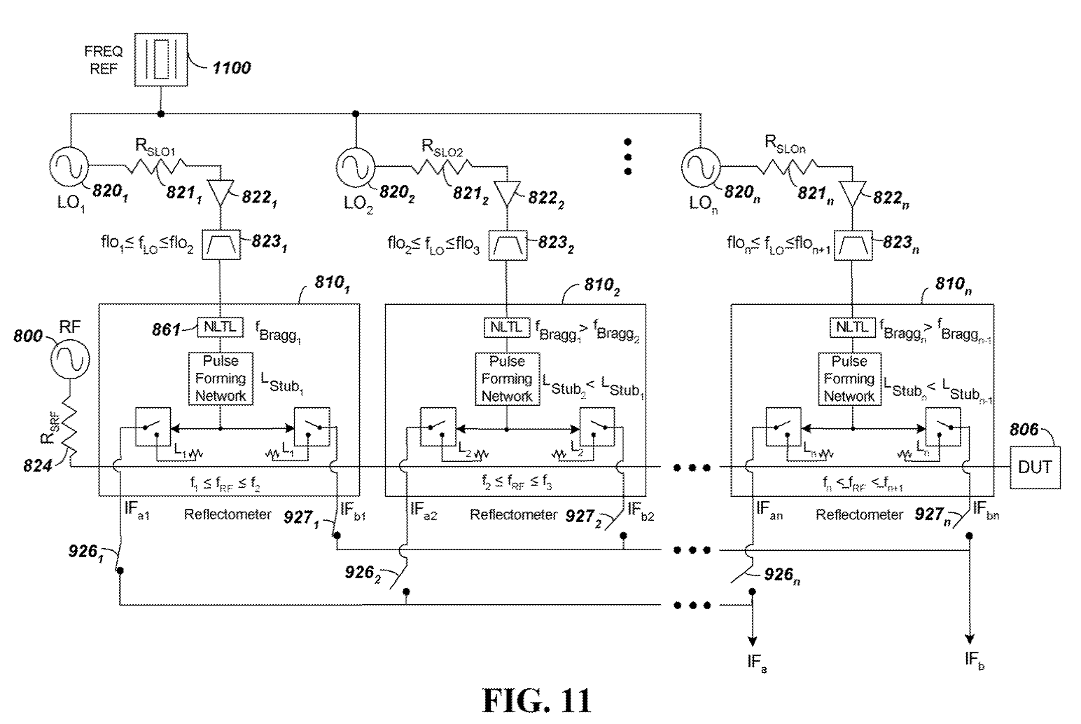

FIG. 11 shows another alternative reflectometer configuration to FIG. 9 that includes an LO distribution circuitry without using couplers. Instead of using couplers, the circuitry of FIG. 11 includes a reference crystal oscillator or other reference frequency source 1100 that is connected to separate LO sources 820₁₋ₙ that feed the reflectometer segments 810₁₋ₙ. The separate LO sources 820₁₋ₙ, labeled LO₁₋ₙ, each operate over a different frequency range and are synchronized by the crystal reference (or other reference frequency source) 1100. The local oscillators 820₁₋ₙ connect through amplifiers 822₁₋ₙ and bandpass filters 823₁₋ₙ to the NLTLs in respective segments 810₁₋ₙ. The bandpass filters 823₁₋ₙ are configured to operate over the successive frequency ranges of the LO sources 820₁₋ₙ, such as f₁≦f_{LO}≦f₂ in bandpass filter 823₁, f₂≦f_{LO}≦f₃ in bandpass filter 823₂ and fₙ≦f_{LO}≦fₙ₋₁ in bandpass filter 823ₙ.

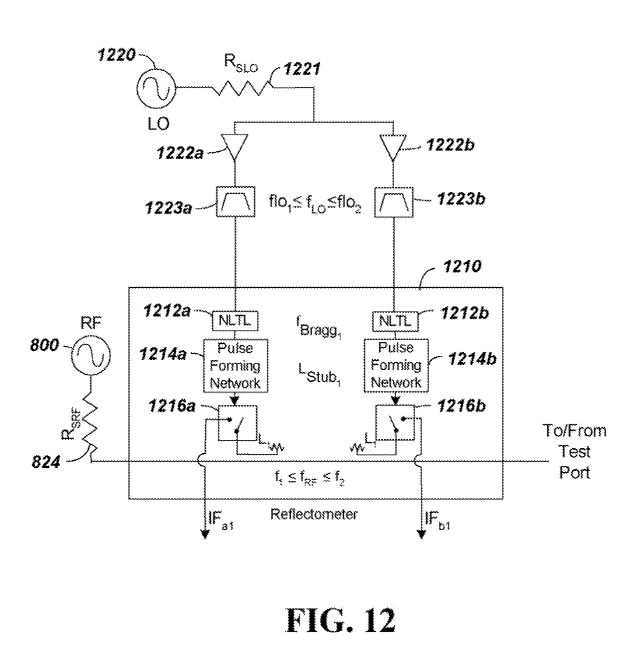

FIG. 12 shows an NLTL sampling circuit segment 1210 providing alternative to segment 810 of FIG. 8 that can be multiplexed with other segments to form a broadband shockline-based sampling reflectometer. The reflectometer circuit segment FIG. 12 differs from FIG. 8 by including separate NLTLs 1212a and 1212b in the test and reference channels as opposed to a single NLTL 812 in FIG. 8. Similarly, instead of a single pulse forming network 814 in FIG. 8, the circuit of FIG. 12 includes two separate pulse forming networks 1212a and 1214b connecting the output of the two NLTLs 1212a and 1212b to respective couplers 1216a and 1216b. The NLTLs 1212a and 1212b and pulse forming networks 1214a and 1214b allow better isolation between the test and reference channels and can be used when a very low noise floor is desired.

With separation of the NLTLs 1212a and 1212b, to achieve greater isolation, the signal from LO source 1220 that is provided through resistor 1221 is separated in a splitter between amplifiers 1222a and 1222b. The output of amplifier 1222a is provided through bandpass filter 1223a to the input of NLTL 1212a. The output of amplifier 1222b is provided through bandpass filter 1223b to the input of NLTL 1223b. The frequency range f_{LO} of bandpass filters 1223a and 1223b is the same at f₁≦f_{LO}≦f₂. As in FIG. 8, a single RF source 800 and resistor 824 supply the RF signal through couplers of the reflectometer section 1210.

Also with the circuitry of FIG. 12, the couplers 1216a and 1216b can be integrated with the individual NLTLs. Like the couplers 1216a and 1216b, the shockline-based sampler can be monolithic, enabling the directional couplers 1216a and 1216b to be integrated onto the same substrate as the respective shocklines 1212a and 1212b. This can improve stability (as in mechanical stability) and raw directivity (precision formation of the coupling structure). Both of these improvements can help increase electrical measurement stability.

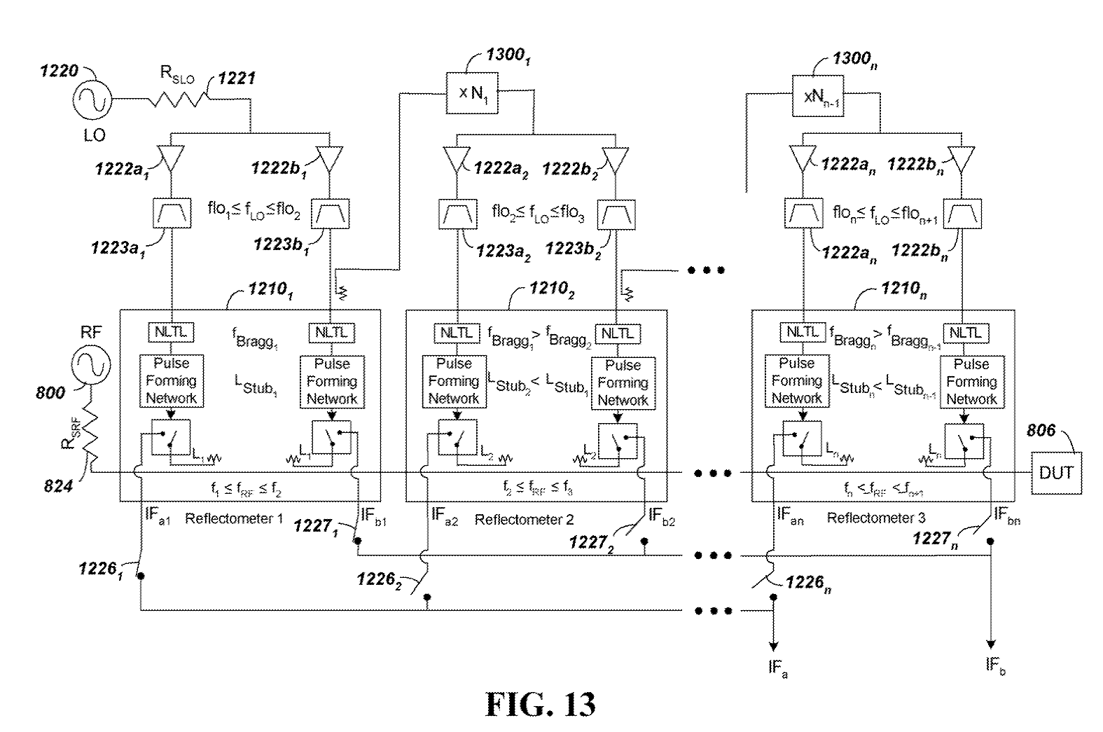

FIG. 13 shows one embodiment of circuitry for multiplexing reflectometer segments as shown in FIG. 12 to form a reflectometer. The reflectometer segments include segments 1210₁₋ₙ that include components similar to those of reflectometer 1210 in FIG. 12, so those components are not individually labeled. The configuration of circuitry in FIG. 13 includes frequency multipliers 1300₁₋ₙ connected by couplers to the NLTL of the first segment 1210₁, similar to interconnection circuitry of FIG. 9.

In FIG. 13, similar to the arrangement of FIG. 9, the internal components of the segments 1200₁₋ₙ include components adjusted so they operate over different successive frequency ranges. For instance reflectometer segment 1210₁ has components set so that the RF frequency range F_{RF} is f₁≦F_{RF}≦f₂. The next reflectometer segment 1210₂ has an F_{RF} occupying the next frequency range f₂≦F_{RF}≦f₃, and so forth till the final segment 1210ₙ that occupies the RF the frequency range fₙ₋₁F_{RF}≦fₙ. The IF distribution system includes a series of switches 1226₁₋ₙ and 1227₁₋ₙ that individually connect the IF outputs of the segments 1210₁₋ₙ to provide output IF signals IFa and IFb.

To provide an LO distribution system in FIG. 13, a sequentially higher frequency LO signal range is provided to each sequential reflectometer segment 1210₁₋ₙ. For the first segment 1210₁, the LO source 1220 from FIG. 12 is provided through a resistance R_{SLO} 1221, amplifiers 1222ₐ₁ and 1221_{b1} and bandpass filters 1223ₐ₁ and 1223_{b1} to the input of the NTLTs in the reflectometer section 1210₁ similar to the segment of FIG. 12. For the next segment 1210₂, the output of bandpass filter 1223_{b1} is provided by a coupler to frequency multiplier 1300₁ through amplifiers 1222ₐ₂ and 1222_{b2} and bandpass filters 1223ₐ₂ and 1223_{b2} to the input of its NLTL 1210₂. The frequency multiplier 1300₁ has a multiplier value N₁ set to provide a slightly increased f_{LO} from f₁≦f_{LO}≦f₂ in segment 1210₁ to f₂≦f_{LO}≦f₃ for segment 1210₂. A similar coupler connects the LO from bandpass filter 1223_{b2} to a subsequent segment. The circuitry continues up to multiplier 1300ₙ with value Nₙ₋₁. The output of multiplier 1300ₙ supplies amplifiers 1222ₐₙ and 1222_{bn} and bandpass filters 1223_{bn} and 1223_{bn} to create an f_{LO}of fₙ≦f_{LO}≦fₙ₋₁ that is input to segment 1210ₙ.

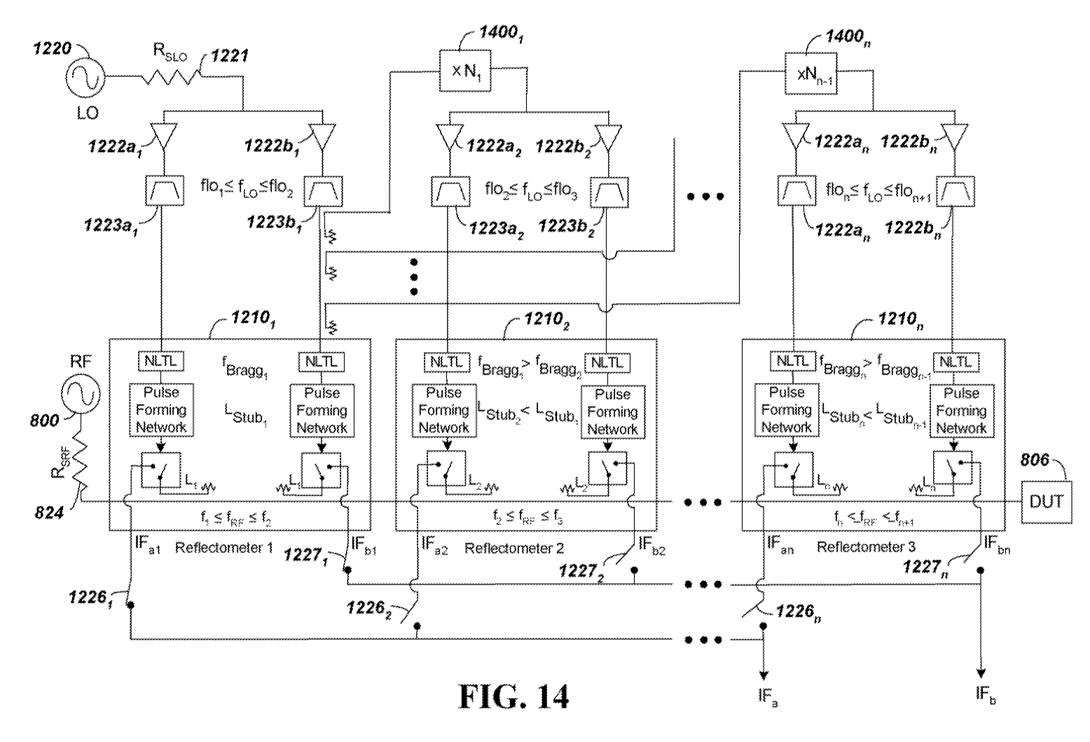

FIG. 14 shows an alternative reflectometer configuration to FIG. 13 that includes an LO distribution circuitry with different LO coupler connections. Similar to FIG. 10, the LO distribution in FIG. 13 is changed to include frequency multipliers 1400₁₋ₙ that all connect by couplers between the output of bandpass filter 1223_{b1} and the input of the first reflectometer segment 1210₁. This configuration prevents the frequency multiplier values N₁ through Nₙ₋₁ in multipliers 1400₁₋ₙ from adversely affecting one another, as they do the multipliers 1300₁₋ₙ in FIG. 13 that are interconnected.

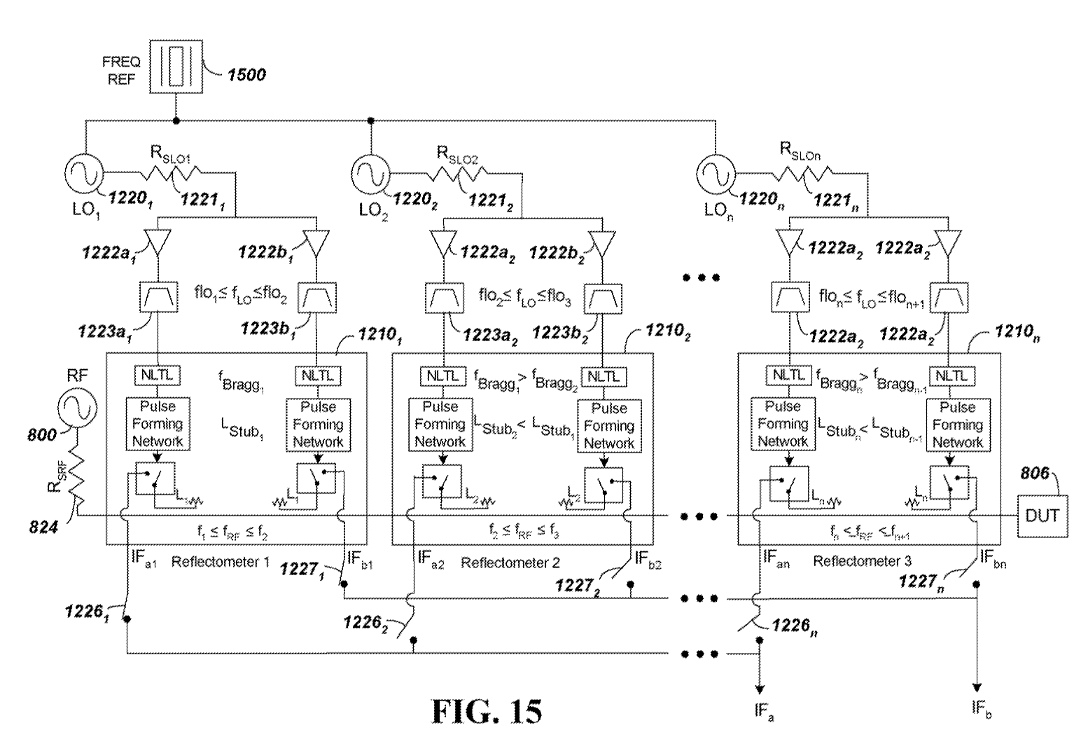

FIG. 15 shows another alternative reflectometer configuration to that of FIGS. 13 and 14 that includes an LO distribution circuitry without using couplers. Instead of using couplers, the circuitry of FIG. 15 includes a reference crystal oscillator (or other reference frequency source) 1500 that is connected to separate LO sources 1220₁₋ₙ that feed the reflectometer segments 1210₁₋ₙ. The separate LO sources 1220₁₋ₙ, labeled LO₁₋ₙ, each operate over a different frequency range and are synchronized by the crystal reference (or other reference frequency source) 1500. The local oscillators 1220₁₋ₙ connect through amplifiers 1222a₁₋ₙ and 1222b₁₋ₙ and bandpass filters 1223₁₋ₙ and 1223b₁₋ₙ to the NLTLs in respective segments 1210₁₋ₙ. The bandpass filters 1223₁₋ₙ are configured to operate over successive frequency ranges of the LO sources 1220₁₋ₙ, such as f₁≦f_{LO}≦f₂ in bandpass filter 1223₁, f₂≦f_{LO}≦f₃ in bandpass filter 1223₂ and fₙ≦f_{LO}≦fₙ₋₁ in bandpass filter 1223ₙ.

### II. NLTL Based RF Source Extension System

To enable the RF test signal provided from a VNA to reach the high frequency range for a NLTL-based sampler described above, an NLTL based source extension may be required. Accordingly circuitry for NLTL based RF source extensions are described to follow. Although the NLTL based source extensions described can be used with a VNA, they are not limited to this use, and can be used with other components such signal generators, synthesizers, tracking generators, and other components needing generation of high frequency broadband RF signals.

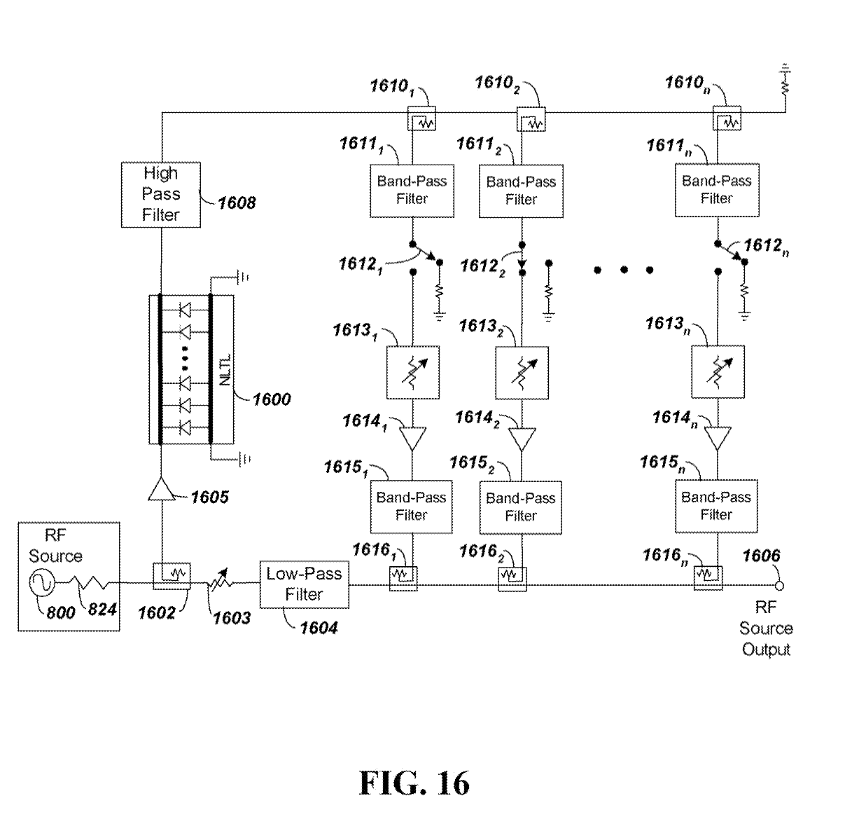

The RF source 800 shown in circuitry prior to FIG. 16 can provide a high frequency output, but in some cases an NLTL circuit might be needed to extend the frequency and range of the RF source 800. The configurations of FIGS. 16 through 18 show such added NLTL circuitry to extend the RF source 800 output. With the added NLTL circuitry, the RF source output connection can be made in place of the RF source 800 in previous figures and will be provided from the RF source output 1606 point shown in FIGS. 16 through 18.

FIG. 16 shows a first configuration of circuitry to implement a shockline based RF source extension that uses a single shockline 1600. The circuitry includes the RF source 800 that can be provided with a standard 50 Ohm output 824. A switch formed by coupler 1602 and attenuator 1603 enables alternatively: (1) providing the RF source through a low pass filter 1604 directly to the RF source output 1606 if a high frequency NLTL generated signal is not required; or (2) providing an output from the RF source through buffer 1605 and NLTL 1600 to subsequent multiplexing circuitry if a high frequency NLTL signal is desired. To accomplish a switching function, the attenuator 1603 is set at full attenuation when the NLTL 1600 is driven, while a zero attenuation is provided by attenuator 1603 when the frequency extension of NLTL 1600 is not required. Also, when the NLTL 1600 is not required and attenuator 1603 is set to zero, all of the switches 16121-n of the multiplexing circuitry are terminated in a load.

In the multiplexing circuitry when the signal is provided through NLTL 1600, output of the NLTL 1600 is provided through a high pass filter 1608 to a multiplexing system. The multiplexing system selects and optimizes one frequency range of the signals provided from the NLTL 1600 to provide as an output at the RF source output 1606.

The multiplexing system begins with couplers 1610₁₋ₙ that selectively provide the signal from NLTL 1600 down one of “n” paths. The first element after couplers 1610₁₋ₙ is one of band pass filters 1611₁₋ₙ. The band pass filters 1611₁₋ₙ are each set with sequential overlapping frequency ranges throughout the desired total frequency range for the system. One of the switches 1612₁₋ₙ is closed to provide a signal from the selected bandpass filters 1611₁₋ₙ of a desired segment to connect to the RF source output 1606, such as the switch 1612₂ shown closed, while the rest remain open.

The output of switches 1612₁₋ₙ are provided to respective variable attenuators 1613₁₋ₙ. The variable attenuators 1613₁₋ₙ can be adjusted so that an equal power profile is provided from each multiplexed segment. The output of the variable attenuators 1613₁₋ₙ are provided through amplifiers 1614₁₋ₙ to boost signal strength due to losses through couplers in the multiplexer system. The output of the amplifiers 1614₁₋ₙ are then provided through bandpass filters 1615₁₋ₙ to minimize any noise introduced in the multiplexing process, and then couplers 1616₁₋ₙ provide the multiplexer output to the RF source output port 1606.

For the RF source extension system shown in FIG. 16, components such as the shocklines, couplers and amplifiers as well as other components can be integrated monolithically. With monolithic integration of the various components, uniform heating and cooling of the substrate can be easily provided with a temperature control apparatus to maintain amplitude and phase stability.

As indicated previously, the source extension can be used with single or multi-port VNAs, tracking generators, synthesizers and other instruments. The source extension can be provided in portable hand-held instruments, benchtop instruments, active probes, or other components. The source extension can be inside or outside of the instrument. The above components that can utilize the source extension of FIG. 16 and its described configurations are likewise available for circuitry described in subsequent figures.

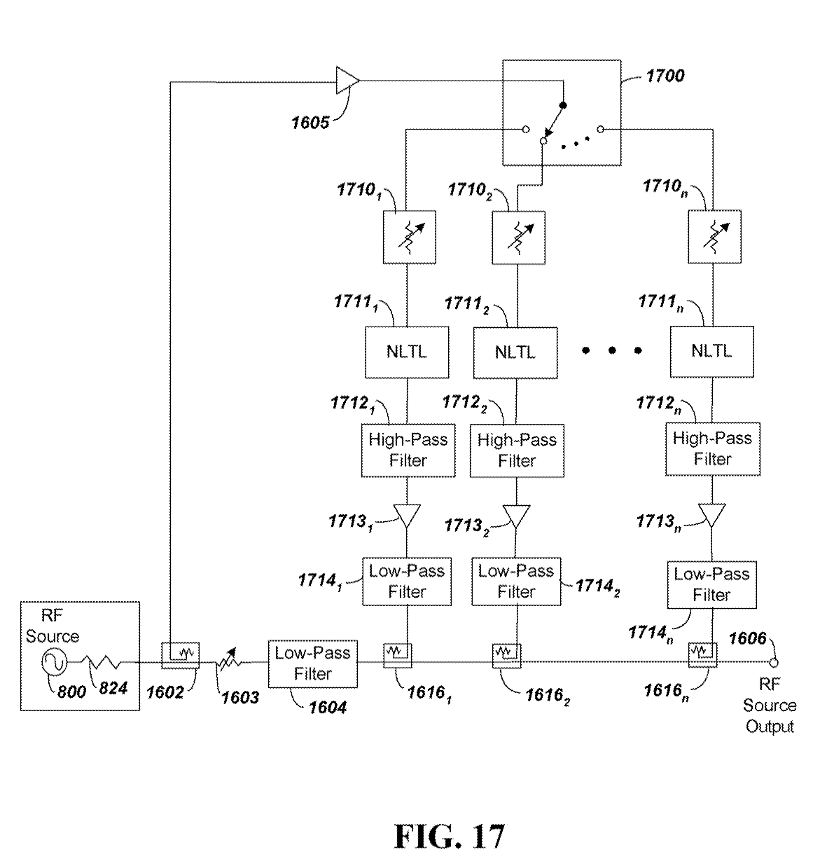

FIG. 17 shows a second configuration of circuitry to implement a shockline based RF source extension that uses multiple multiplexed shocklines 1711₁₋ₙ instead of the single shockline 1600 of FIG. 16. The multiple shocklines 1711₁₋ₙ allow a broader bandwidth of low noise signals than the circuit of FIG. 16.

As in FIG. 17, the RF source 800 is provided through a switch made up of coupler 1602 and attenuator 1603 to one of two paths. A first path provides the RF source 800 signal directly through low pass filter 1604 and couplers 1616₁₋ₙ to the output of RF source 1606, as in FIG. 16. The second path provides the output of RF source 800 through a buffer 1605 to a switch 1700. The switch 1700 effectively replaces the couplers 1610₁₋ₙ and switches 1612₁₋ₙ of FIG. 16. The switch 1700 directs signals through attenuators 1710₁₋ₙ to one of the NLTLs 1711₁₋ₙ. The attenuators 1711₁₋ₙ provide a signal to the NLTLs 1711₁₋ₙ to a desired level to maximize performance of the NLTLs 1711₁₋ₙ. Individual NLTLs can be tuned to maximize performance over successive frequency range segments by techniques such as adjusting the spacing between varactor diodes as discussed previously.

The output of the NLTLs 1711₁₋ₙ are provided through high pass filters 1712₁₋ₙ to remove noise and unwanted harmonics created outside the desired frequency band, and then provided through amplifiers 1713₁₋ₙ to low pass filters 1714₁₋ₙ. The low pass filters suppress harmonics and noise outside the desired frequency range. The final signal is then provided through one of couplers 1715₁₋ₙ to the RF source output 1606.

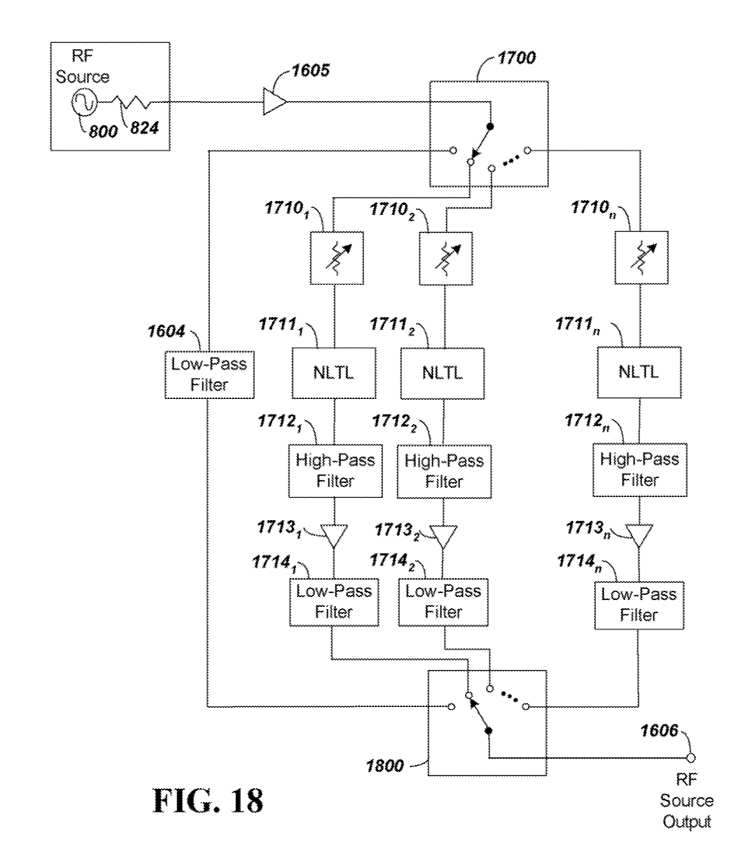

FIG. 18 shows a third configuration of circuitry to implement a shockline based RF source extension that eliminates the couplers used in the circuitry of FIGS. 16 and 17. The switch 1800 replaces the couplers 1616₁₋ₙ of FIGS. 16 and 17 to eliminate the need for couplers in the multiplexing circuitry completely. The configuration of FIG. 18 uses multiple multiplexed shocklines 1711₁₋ₙ as in FIG. 17, but could likewise be used in a configuration with a single shockline as in FIG. 16 to similarly eliminate the need for couplers.

In FIG. 18, the source 800 is provided through an amplifier 1603 directly to switch 1700 instead of through a coupler 1602 and attenuator 1603 as in FIGS. 16 and 17. The direct path from source 800 through low pass filter 1605 to the RF source output 1606 is then provided as one path between switches 1700 and 1800. The NLTLs 1711₁₋ₙ are likewise provided between switches 1700 and 1800, so that they provide multiplexed selection of different segments containing the RF source 800 directly, or through one of the NLTLs 1711₁₋ₙ. The circuitry of FIG. 18 otherwise matches the components of FIG. 17.

Although FIGS. 16-18 show configurations for providing NLTL source extensions, it is understood that other configurations might likewise be provided. For example, one configuration could use the multiplexer 1800 of FIG. 18, but use the couplers 1610₁₋ₙ of FIG. 16 instead of multiplexer 1700.

Although the present invention has been described above with particularity, this was merely to teach one of ordinary skill in the art how to make and use the invention. Many additional modifications will fall within the scope of the invention, as that scope is defined by the following claims.

What is claimed:

1. A shockline-based signal source extension system comprising:
an RF signal source; and
a signal source extension comprising a multiplexer for selectively providing an output from the RF signal source through at least one shockline as an extended RF signal source output.

2. The shockline-based system of claim 1, wherein the at least one shockline of the signal source extension comprises a single shockline, and the multiplexer comprises:
a plurality of first couplers having through paths connected in series to the RF signal source and coupling paths providing multiplexed segments;
switches connected to respective ones of the multiplexed segments, the switches being controlled to connect a signal through one of the multiplexed segments, while opening remaining ones of the multiplexed segments;
filters connecting to respective ones of the switches, the filters separating a frequency range provided in respective ones of the multiplexed segments;
amplifiers provided in respective ones of the multiplexed segments;
attenuators provided in respective ones of the multiplexed segments; and
a plurality of second couplers having coupling paths connected to the filters of respective ones of the multiplexed segments and through paths connecting to the extended RF signal source output.

3. The shockline-based system of claim 2, further comprising:
an RF source selection switch for selectively connecting the RF signal source to the plurality of first couplers or to the through path of the second couplers to the extended RF signal source output.

4. The shockline-based system of claim 3, wherein the switch comprises:
a coupler having a coupling path connected to the at least one shockline, and having a through path connected on a first end to the RF signal source; and
a variable attenuator having a first end connected to a second end of the through path of the coupler and a second end connect to the extended RF signal source output, wherein the variable attenuator is controlled to provide a high attenuation when the switch is to connect to the at least one shockline and a low attenuation when the switch is to connect to the extended RF signal source output.

5. The shockline-based system of claim 2, wherein the at least one shockline, the first couplers, the filters, the amplifiers, the attenuators and the second couplers are integrated monolithically.

6. The shockline-based system of claim 1, wherein the at least one shockline of the signal source extension comprises a plurality of shocklines, and the multiplexer comprises:
a primary switch having a primary connection connected to the RF signal source and a switchable connections for providing multiplexed segments connected to individual ones of the plurality of shocklines;
filters provided in respective ones of the multiplexed segments;
amplifiers provided in respective ones of the multiplexed segments;
attenuators provided in respective ones of the multiplexed segments; and
a plurality of output couplers having coupling paths connected to respective ones of the multiplexed segments and through paths connecting to the extended RF signal source output.

7. The shockline-based system of claim 6, further comprising:
an RF source selection switch for selectively connecting the RF source to the plurality of first couplers or to the through path of the output couplers to the extended RF signal source output.

8. The shockline-based system of claim 7, wherein the switch comprises:
a coupler having a coupling path connected to the at least one shockline, and having a through path connected on a first end to the RF signal source; and
a variable attenuator having a first end connected to a second end of the through path of the coupler and a second end connect to the extended RF signal source output, wherein the variable attenuator is controlled to provide a high attenuation when the switch is to connect to the at least one shockline and a low attenuation when the switch is to connect to the extended RF signal source output.

9. The shockline-based system of claim 6, wherein the primary switch, the plurality of shocklines, the filters, the amplifiers, the attenuators and the output couplers are integrated monolithically.

10. The shockline-based system of claim 1, wherein the at least one shockline of the signal source extension comprises a plurality of shocklines, and the multiplexer comprises:
a primary switch having a primary connection connected to the RF signal source and a switchable connections for providing multiplexed segments connected to individual ones of the plurality of shocklines;
filters connecting to respective ones of the shocklines in the multiplexed segments; and
a secondary switch selectively connecting respective ones of the multiplexed segments to the extended RF signal source output.

11. The shockline-based system of claim 10, further comprising a path between the primary switch and the secondary switch that does not contain a shockline to connect the RF signal source to the RF signal source output.

12. The shockline-based system of claim 1 including a receiver comprising:
a local oscillator signal generated by a shockline; and
a sampler receiving the extended RF signal source output and the local oscillator signal as inputs.

13. The shockline-based system of claim 1 provided in at least one of: a vector network analyzer, a tracking generator and a synthesizer.

14. The shockline-based system of claim 1 provided in at least one of: a portable instrument, a benchtop instrument and an active probe.

15. The shockline-based system of claim 1 further comprising a temperature control apparatus set to maintain amplitude and phase stability.

16. A shock-line based system of claim 1, wherein the at least one shockline comprises a plurality of shocklines each composed of transmission lines with diodes connected in-between, wherein each of the shocklines has different spacings between diodes than other ones of the shocklines.

17. A method for extending the frequency range of a signal source comprising:
providing an RF signal source; and
multiplexing an output of the RF signal source through a plurality of shocklines to selectively provide an extended RF signal source output.

18. The method of claim 17, wherein the plurality of shocklines are altered relative to one another to scale the frequency range of the signal source.
